(19) United States
(12) Patent Application Publication
(10) Pub. No.: US 2025/0331116 A1
(43) Pub. Date: Oct. 23, 2025

(54) TOOL-ACTUATED SLIDE LATCH MECHANISM FOR PREVENTING PREMATURE REMOVAL OF INFORMATION HANDLING RESOURCES

(71) Applicant: Dell Products L.P., Round Rock, TX (US)

(72) Inventors: Eduardo ESCAMILLA, Round Rock, TX (US); Robert G. BASSMAN, Dalton, MA (US); John DONACHY, Austin, TX (US)

(73) Assignee: Dell Products L.P., Round Rock, TX (US)

(21) Appl. No.: 18/640,807

(22) Filed: Apr. 19, 2024

(51) Int. Cl. H05K 7/14

(52) U.S. Cl. CPC H05K 7/1409

(57) ABSTRACT

A slide latch mechanism may include a lever arm and a slide latch. The slide latch may be configured to mechanically engage with the lever arm in a first position and mechanically disengage with the lever arm in a second position, and the slide latch may be further configured such that a tool is required to slide the slide latch from the first position to the second position.

### TECHNICAL FIELD

The present disclosure relates in general to information handling systems, and more particularly to a tool-actuated slide latch mechanism for preventing premature removal of information handling resources.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems may often include information handling resources (e.g., storage devices, input/output devices, and other peripheral devices) that may be manufactured in a modular form factor and may be configured to be disposed in a chassis configured to receive such modular components. Such a chassis and its component modular information handling systems and information handling resources typically include various rails, carriers, and other mechanical components allowing for a person to add and remove the modular information handling systems and information handling resources from the chassis.

Certain types of information handling resources, referred to as “cold-service” information handling resources, may be removed only after an information handling system has powered down. If a cold-service information handling resource is removed prematurely, the information handling system may abruptly shut down and lead to data loss. Other types of information handling resources, referred to as “hot-service” information handling resources, may be removed while the information handling system remains powered on without leading to such abrupt information handling system shut down and data loss. Both types of information handling resources may appear similar to a user and may exist within the same information handling system. Consequently, users frequently mistake cold-service information handling resources for hot-service information handling resources, which often results in premature removal of a cold-service information handling resource (e.g., while the information handling system is powered on). Accordingly, systems and methods for differentiating between cold-service information handling resources and hot-service information handling resources to prevent such premature removal may be desired.

### SUMMARY

In accordance with the teachings of the present disclosure, the disadvantages and problems associated with existing approaches to preventing premature removal of cold-service information handling resources may be eliminated or reduced.

In accordance with embodiments of the present disclosure, a slide latch mechanism may include a lever arm and a slide latch. The slide latch may be configured to mechanically engage with the lever arm in a first position and mechanically disengage with the lever arm in a second position, and the slide latch may be further configured such that a tool is required to slide the slide latch from the first position to the second position.

In accordance with embodiments of the present disclosure, an information handling system may include at least one cold-service information handling system configured to be removed from the information handling system after the information handling system is powered down. The at least one cold-service information handling resource may include a slide latch mechanism, which may include a lever arm and a slide latch. The slide latch may be configured to mechanically engage with the lever arm in a first position and mechanically disengage with the lever arm in a second position, and the slide latch may be further configured such that a tool is required to slide the slide latch from the first position to the second position.

In accordance with embodiments the of present disclosure, a method of making a slide latch mechanism includes mechanically coupling a lever arm to a pivot and mechanically coupling a slide latch to a first spring configured to bias the slide latch to a first position. The slide latch may be configured to mechanically engage with the lever arm in the first position and mechanically disengage with the lever arm in a second position. The slide latch may further be configured such that a tool is required to slide the slide latch from the first position to the second position.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a front elevation view of an example information handling system comprising example hot-service information handling resources and example cold-service information handling resources, in accordance with embodiments of the present disclosure;

FIG. 2 illustrates a perspective view of selected components of an example cold-service information handling resource comprising an example tool-actuated slide latch mechanism, in accordance with embodiments of the present disclosure; and

FIG. 3 illustrates a cross-sectional, perspective view of selected components of an example cold-service information handling resource comprising an example slide tool-actuated slide latch mechanism, in accordance with embodiments of the present disclosure.

### DETAILED DESCRIPTION

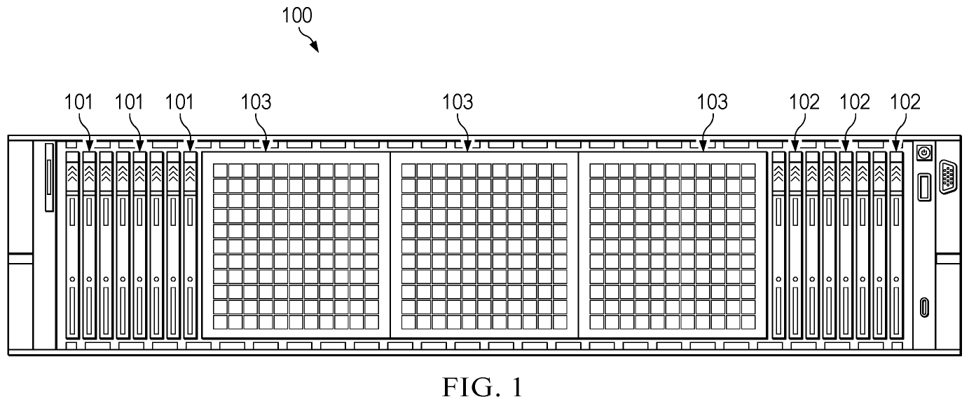

Preferred embodiments and their advantages are best understood by reference to FIGS. 1 through 3, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal data assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies. Such information handling resources may include various rails, carriers, and other mechanical components allowing for a person to add and remove the information handling resources from a chassis.

FIG. 1 illustrates a front elevation view of an example information handling system 100 comprising example cold-service information handling resources 101 and example hot-service information handling resources 102, in accordance with embodiments of the present disclosure. As shown in FIG. 1, information handling system 100 may further comprise airflow blanks 103. In addition to cold-service information handling resources 101, hot-service information handling resources 102, and airflow blanks 103, information handling system 100 may include one or more other information handling resources.

Proper removal of cold-service information handling resources 101 from information handling system 100 may require information handling system 100 to be powered down prior to removal. Premature removal of cold-service information handling resources 101 (e.g., before information handling system 100 is powered down) may cause information handling system 100 to abruptly shut down, which may lead to data loss. In contrast, hot-service information handling resources 102 may be safely removed while information handling system 100 is powered on. As further described below, cold-service information handling resources 101 may comprise a tool-actuated slide latch mechanism to facilitate user discernment between cold-service information handling resources 101 and hot-service information handling resources 102, which may prevent premature removal of cold-service information handling resources 101 from information handling system 100.

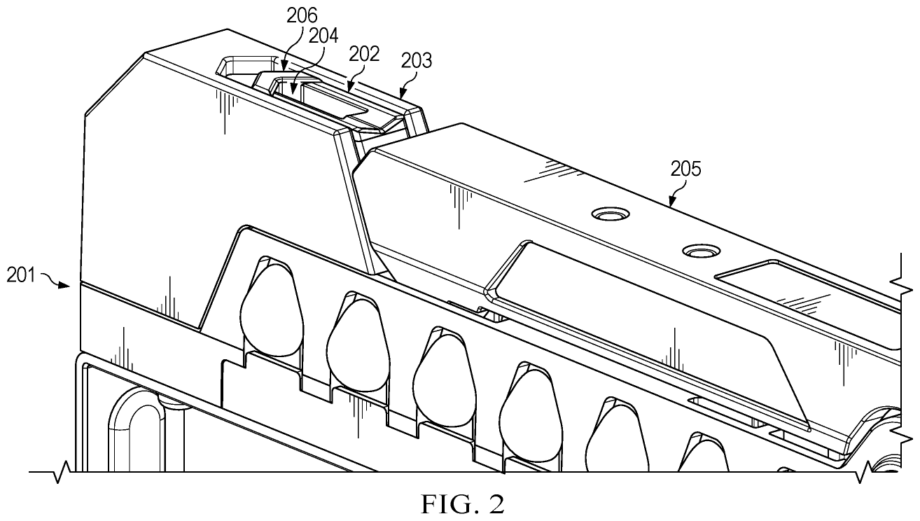

FIG. 2 illustrates a perspective view of an example cold-service information handling resource 201 comprising an example tool-actuated slide latch mechanism, in accordance with embodiments of the present disclosure. As shown in FIG. 2, a tool-actuated slide latch mechanism may comprise a slide latch 202 configured to mechanically engage (e.g., mechanically coupled to) with a lever arm 205 such that lever arm 205 is in a “closed” position. In some embodiments, lever arm 205 may be spring-loaded such that lever arm 205 may be biased towards an “open” position. Thus, when slide latch 202 and lever arm 205 mechanically disengage (e.g., mechanically decouple), lever arm 205 may release to an “open” position, enabling removal of cold-service information handling resource 201 from an information handling system.

As shown in FIG. 2, slide latch 202 may comprise recess 204. Recess 204 may be sufficiently deep and adjacent features sufficiently small such that a user may be unable to grip slide latch 202 and/or may find it difficult to move slide latch 202 without a tool. A top surface of slide latch 202 may be substantially flush with surfaces adjacent to the top surface of slide latch 202 (e.g., a top surface 203 of cold-service information handling resource 201). In some embodiments, the top surface of slide latch 202 may be substantially sub-flush with surfaces adjacent to the top surface of slide latch 202 (e.g., top surface 203 of information handling system 201). As described further below, slide latch 202 may thus be configured such that a tool may be required to actuate slide latch 202 to release lever arm 205 (e.g., move slide latch 202 such that slide latch 202 and lever arm 205 mechanically disengage or decouple), enabling removal of cold-service information handling resource 201 from an information handling system.

In some embodiments, a user may actuate slide latch 202 by inserting a tool in recess 204 to move slide latch 202 from a first position to a second position, releasing lever arm 205 and enabling removal of cold-service information handling resource 201. Slide latch 202 may be configured such that a variety of tools may be suitable to actuate slide latch 202. A non-exhaustive, illustrative list of such suitable tools includes a spudger, screwdriver, pen, pen top, bezel key, or custom tool. Thus, the features of slide latch 202 and lever arm 205 as described above may be configured such that a user may be unable to generate or may experience difficulty in generating sufficient mechanical leverage to actuate slide latch 202 and release lever arm 205 without a tool.

In some embodiments, slide latch 202 may further comprise a visual indicator that may visually direct a user as to a direction slide latch 202 may slide to release lever arm 205. For example, as shown in FIG. 2, a portion 206 of slide latch 202 may be formed substantially as an arrow indicating the direction slide latch 202 may slide to release lever arm 205. While FIG. 2 depicts portion 206 of slide latch 202 formed substantially as an arrow, one of ordinary skill in the art may understand that slide latch 202 may comprise any visual indicator suitable for informing a user as to the direction slide latch 202 may slide to release lever arm 205.

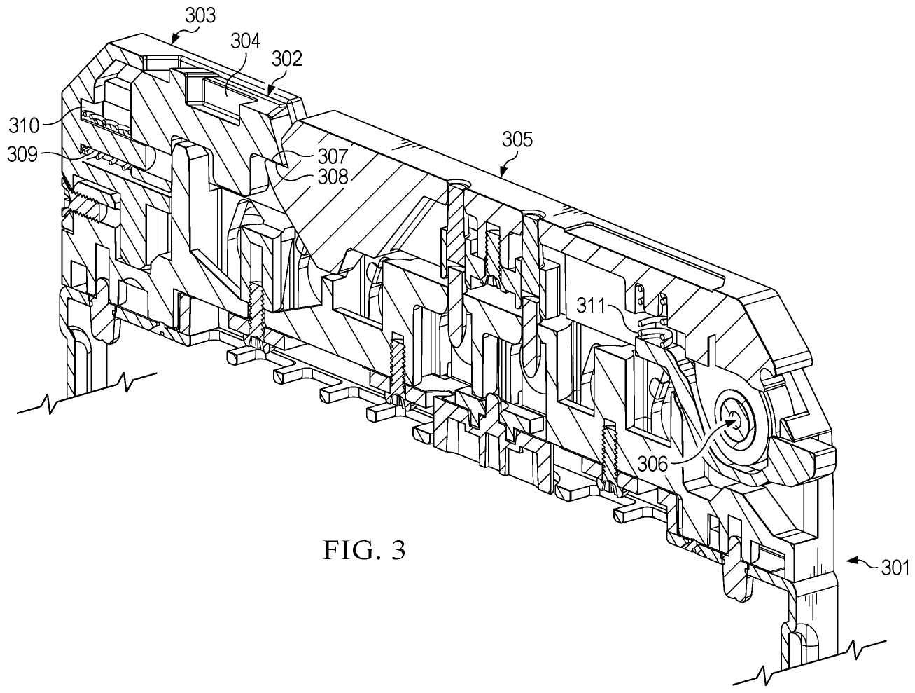

FIG. 3 illustrates a cross-sectional, perspective view of selected components of an example cold-service information handling resource 301 comprising an example tool-actuated slide latch mechanism, in accordance with embodiments of the present disclosure. As shown in FIG. 3, a tool-actuated slide latch mechanism may comprise a slide latch 302. A top surface of slide latch 302 may be substantially flush with a top surface 303 of cold-service information handling resource 301. In some embodiments, the top surface of slide latch 302 may be substantially sub-flush with top surface 303. Cold-service information handling resource 301 may further comprise a spring 309 mechanically coupled between slide latch 302 and internal wall 310 of cold-service information handling resource 301. Spring 309 may be configured to bias slide latch 302 to a first position. A tool may be required to actuate slide latch 302. In some embodiments, the tool may be inserted into recess 304 to apply a force to move slide latch 302 from the first position to a second position, which may compress spring 309. A non-exhaustive, illustrative list of such suitable tools includes a spudger, screwdriver, pen, pen top, bezel key, or custom tool.

The tool-actuated slide latch mechanism may further comprise lever arm 305. Lever arm 305 may be configured to mechanically engage with (e.g., mechanically couple to) slide latch 302 in a “closed” position. In some embodiments, spring 311 may bias lever arm 305 towards an “open” position. Thus, when slide latch 302 and lever arm 305 mechanically disengage (e.g., mechanically decouple), lever arm 305 may release to an “open” position, enabling removal of cold-service information handling resource 301 from an information handling system.

In operation, slide latch 302 may be mechanically engaged with (e.g., mechanically coupled to) lever arm 305 when slide latch 302 is in a first position and lever arm 305 is in a “closed” position. A user may insert a tool into recess 304 of slide latch 302 and move slide latch 302 in a direction of a visual indicator from the first position to a second position, thereby compressing spring 309. As slide latch 302 slides from the first position to the second position, slide latch 302 may mechanically disengage (e.g., mechanically decouple) from lever arm 305 and spring 311 may decompress such that lever arm 305 may rotate around pivot 306 and release from a “closed” position to an “open” position. Cold-service information handling resource 301 may then be removed from an information handling system.

When the tool is removed from recess 304, slide latch 302 may automatically return to the first position due to force exerted by spring 309. To return lever arm 305 to a “closed” position in which slide latch 302 and lever arm 305 are mechanically engaged (e.g., mechanically coupled), a user may apply a downward force to lever arm 305 such that lever arm 305 rotates around pivot 306 and contacts slide latch 302. As a user continues to apply a downward force to lever arm 305, lever arm 305 may move slide latch 302 from the first position towards the second position, thereby compressing spring 309 and compressing spring 311. Lever arm 305 may continue to move slide latch 302 towards the second position until interlocking component 308 of lever arm 305 is sufficiently beneath interlocking component 307 of slide latch 302 such that slide latch 302 may automatically return to the first position due to force exerted by spring 309, locking slide latch 302 and lever arm 305 in a mechanically engaged, “closed” position.

While FIGS. 1 through 3 illustrate a tool-actuated slide latch mechanism compatible with a cold-service information handling resource having a first form factor, one of ordinary skill in the art would understand that the tool-actuated slide latch mechanism disclosed herein may be configured to be suitable with a cold-service information handling resource having a different form factor.

Furthermore, while FIGS. 1 through 3 discuss a tool-actuated slide latch mechanism in context of cold-service information handling resources, one of ordinary skill in the art may appreciate that the tool-actuated slide latch mechanism disclosed herein may be used with other information handling resources in which it is desirable to prevent premature removal of such information handling resources.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. A slide latch mechanism comprising:
a lever arm; and
a slide latch configured to:
mechanically engage with the lever arm in a first position; and
mechanically disengage with the lever arm in a second position, wherein the slide latch is configured such that a tool is required to slide the slide latch from the first position to the second position.

2. The slide latch mechanism of claim 1, further comprising a first spring configured to bias the slide latch towards the first position.

3. The slide latch mechanism of claim 2, wherein, as the lever arm moves from an open position to a closed position, the slide latch is configured to:
slide from the first position, due to force exerted by the lever arm, towards the second position; and
automatically return to the first position, due to force exerted by the first spring, as the lever arm reaches the closed position.

4. The slide latch mechanism of claim 2 further comprising:
a pivot around which the lever arm is configured to rotate; and
a second spring configured to bias the lever arm towards an open position such that the lever arm automatically releases towards the open position when the slide latch and lever arm mechanically disengage.

5. The slide latch mechanism of claim 1, wherein the slide latch mechanism is configured to:
lock a cold-service information handling resource in an information handling system when the lever arm and slide latch are mechanically engaged; and
release the cold-service information handling resource for removal from the information handling system when the lever arm and slide latch are mechanically disengaged.

6. The slide latch mechanism of claim 1, wherein the slide latch further comprises a visual indicator indicating a direction in which the slide latch moves to mechanically disengage from the lever arm.

7. The slide latch mechanism of claim 1, wherein a top surface of the slide latch is substantially flush or sub-flush with an adjacent surface.

8. An information handling system comprising:
at least one cold-service information handling resource configured to be removed from the information handling system after the information handling system is powered down, wherein the at least one cold-service information handling resource comprises:
a slide latch mechanism comprising:
a lever arm; and
a slide latch configured to:
mechanically engage with the lever arm in a first position; and
mechanically disengage with the lever arm in a second position, wherein the slide latch configured such that a tool is required to slide the slide latch from the first position to the second position.

9. The information handling system of claim 8, wherein the slide latch mechanism further comprises a first spring configured to bias the slide latch towards the first position.

10. The information handling system of claim 9, wherein, as the lever arm moves from an open position to a closed position, the slide latch is configured to:
slide from the first position, due to force exerted by the lever arm, towards the second position; and
automatically return to the first position, due to force exerted by the first spring, as the lever arm reaches the closed position.

11. The information handling system of claim 9, wherein the slide latch mechanism further comprises:
a pivot around which the lever arm is configured to rotate; and
a second spring configured to bias the lever arm towards an open position such that the lever arm automatically releases towards the open position when the slide latch and lever arm mechanically disengage.

12. The information handling system of claim 8, wherein the slide latch mechanism is configured to:
lock the at least one cold-service information handling resource in the information handling system when the lever arm and slide latch are mechanically engaged; and
release the at least one cold-service information handling resource for removal from the information handling system when the lever arm and slide latch are mechanically disengaged.

13. The information handling system of claim 8, wherein the slide latch further comprises a visual indicator indicating a direction in which the slide latch moves to mechanically disengage from the lever arm.

14. The slide latch mechanism of claim 8, wherein a top surface of the slide latch is substantially flush or sub-flush with an adjacent surface.

15. A method of making a slide latch mechanism comprising:
mechanically coupling a lever arm to a pivot; and
mechanically coupling a slide latch to a first spring configured to bias the slide latch to a first position, wherein the slide latch is configured to:
mechanically engage with the lever arm in the first position; and
mechanically disengage with the lever arm in a second position, and wherein the slide latch is further configured such that a tool is required to slide the slide latch from the first position to the second position.

15. he method of claim 15 further comprising:
mechanically coupling a second spring to the lever arm, wherein the second spring is configured to bias the lever arm towards an open position such that the lever arm automatically releases towards the open position when the slide latch and lever arm mechanically disengage.

17. The method of claim 15, wherein as the lever arm moves from an open position to a closed position, the slide latch is configured to:
slide from the first position, due to force exerted by the lever arm, towards the second position; and
automatically return to the first position, due to force exerted by the first spring, as the lever arm reaches the closed position.

18. The method of claim 15, wherein the slide latch mechanism is configured to:
lock a cold-service information handling resource in an information handling system when the lever arm and slide latch are mechanically engaged; and
release the cold-service information handling resource for removal from the information handling system when the lever arm and slide latch are mechanically disengaged.

19. The method of claim 15, wherein the slide latch further comprises a visual indicator indicating a direction in which the slide latch moves to mechanically disengage from the lever arm.

20. The method of claim 15, wherein a top surface of the slide latch is substantially flush or sub-flush with an adjacent surface.
